(19) United States
(12) Patent Application Publication
(10) Pub. No.: US 2009/0211902 A1
(43) Pub. Date: Aug. 27, 2009

(54) SPUTTERING TARGET

(75) Inventors: Hideo FUJII, Hyogo (JP); Hitoshi Matsuzaki, Hyogo (JP)

Correspondence Address: OBLON, SPIVAK, MCCLELLAND MAIER & NEUSTADT, P.C., 1940 DUKE STREET, ALEXANDRIA, VA, 22314, US

(73) Assignees: Kabushiki Kaisha Kobe Seiko Sho(Kobe Steel, Ltd.), Kobe-shi (JP); KOBELCO RESEARCH INSTITUTE, INC., Kobe-shi (JP)

(21) Appl. No.: 12/391,487

(22) Filed: Feb. 24, 2009

(30) Foreign Application Priority Data
Feb. 25, 2008 (JP) 2008-043218

(51) Int. Cl. C23C 14/34

(52) U.S. Cl. 204/298.13

(57) ABSTRACT

The present invention provides a sputtering target in which an occurrence of target cracks can be inhibited. The sputtering target of the invention relates to a sputtering target produced by mixing and sintering a main powder containing In as a main component, which is obtained by pulverizing an ingot consisting of an intermetallic compound, and a sub-powder containing a different component composition from the above-mentioned main powder, wherein a total content of Si, Al and Fe which are unavoidable impurities is 300 ppm by mass or less. Further, the intermetallic compound contains In and at least one selected from Co and Ni.

### CROSS-REFERENCE TO RELATED APPLICATIONS

This application claims priority from Japanese Patent Application No. 2008-043218 filed on Feb. 25, 2008, the entire subject matter of which is incorporated herein by reference.

### BACKGROUND OF THE INVENTION

1. Field of the Invention

The present invention relates to a sputtering target used for forming a recording film for an optical information recording medium for punching recording or a mask film for thermal lithography. Incidentally, the invention will be explained mainly with reference to the recording film for an optical information recording medium for punching recording as follows. However, the invention can also be similarly applied to the mask film for thermal lithography.

2. Description of the Background Art

In recent years, as an optical information recording medium, BD-R which is a write-once optical disk called a next generation type using a blue laser has come to be used in place of CD-R or DVD-R which is a write-once optical disk using a red laser. Al, Ag, Cu or the like is generally used as a recording film of BD-R. However, as a result of intensive experiments and studies made by the present inventors, it has been found that use of an In alloy containing at least one element selected from Ni and Co in an amount of 20 to 65 atomic % can realize not only a high reflectance (initial reflectance), but also a high C/N ratio of an 8 T signal, which has previously been applied for a patent.

For example, when the In alloy containing Co as an added element is used as the recording film of BD-R, the In alloy is desirably adjusted to have a content of Co of 40 atomic % or more, in view of characteristics of the optical disk. However, when a melting process generally used in the production of a sputtering target used for the formation of the recording film is employed, a melting temperature thereof reaches 1,300° C. or more (see FIG. 1), resulting in evaporation of In having a low melting point, whereas resulting in Co left unmelted, which poses a problem that it becomes impossible to produce the sputtering target having an alloy composition controlled. For this reason, it is necessary to apply a powder process which is another process generally used to produce the sputtering target.

However, In itself is extremely soft. Accordingly, even when a powder is tried to be obtained by an atomize process (a process of spraying a gas to a molten metal flowing out from a nozzle after melting to solidify droplets, thereby produce a powder), it is impossible to obtain the powder.

Then, the present inventors have come up with a process of once producing by the melting process an ingot consisting of an intermetallic compound within a composition range where the production thereof is possible, pulverizing the ingot to form a main powder, and making up for the content of a component (element) insufficient to a final component composition, when only the main powder is used, by a sub-powder separately prepared. The intermetallic compound is a compound composed of two or more kinds of metals, and shows specific physical and chemical properties different from those of the component elements. For example, an ingot consisting of an intermetallic compound Co₃In in an In—Co-based alloy has a high hardness, and pulverization thereof can provide a main powder having a small variation in particle size. The main powder and the sub-powder are mixed and sintered, whereby it becomes possible to produce the sputtering target having a component composition.

In-containing sputtering targets are described in patent document 1 and patent document 2. However, all of them have been applied for patents based on technology devised for the purpose of achieving a deterioration inhibiting effect of magnetic characteristics or a particle inhibiting effect in sputtering, but these patent applications do not relate to technology in which attention is focused on improvement of a decrease in yield associated with the occurrence of cracks in the In alloy sputtering target.

Patent document 1 describes technology relating to a low-oxygen-containing alloy having magnetic characteristics useful for magnetic memory applications and a sputtering target formed by this alloy. As the In-containing sputtering target, there is described a sputtering target comprising Mn and In. Further, this sputtering target is produced merely by a melting process casting process.

Patent document 2 describes technology relating to a Ge—In—Sb—Te alloy sputtering target for an optical recording medium and an optical recording medium having a recording film of the alloy. However, this sputtering target comprises an In having a component ratio as low as 1 to 10 atomic %, and is produced by a mere powder process.

[Patent Document 1] JP-A-2006-111963

[Patent Document 2] Domestic Re-publication of PCT Patent Application WO 2005/005683

### SUMMARY OF THE INVENTION

The invention has been made intending to solve the above-mentioned conventional problems, and it is an object of the invention to provide a sputtering target not only having a component composition, which can not be produced only by a production process such as a mere melting process or powder process, but also being able to inhibit the occurrence of target cracks which are likely to occur in the target itself.

[1] A sputtering target produced by mixing and sintering a main powder containing In as a main component, which is obtained by pulverizing an ingot consisting of an intermetallic compound, and a sub-powder containing a component composition different from the main powder, wherein the total content of Si, Al and Fe which are unavoidable impurities is 300 ppm by mass or less.

[2] The sputtering target according to [1], which contains In and an intermetallic compound containing at least one element selected from the group consisting of Co and Ni.

[3] The sputtering target according to [1], which contains Co in an amount of 20 to 65 atomic %.

[4] The sputtering target according to [2], which contains Co in an amount of 20 to 65 atomic %.

[5] The sputtering target according to [2], which further contains at least one element selected from the group consisting of Sn, Ge and Bi.

[6] The sputtering target according to [3], which further contains at least one element selected from the group consisting of Sn, Ge and Bi.

[7] The sputtering target according to [4], which further contains at least one element selected from the group consisting of Sn, Ge and Bi.

[8] The sputtering target according to any one of [1] to [7], wherein a content of oxygen is 3,000 ppm by mass or less.

According to the sputtering target of the invention, the sputtering target containing In as a main component, which is difficult to be produced only by a production process such as a mere melting process or powder process, can be surely produced, and moreover, the occurrence of target cracks which are likely to occur in the target itself can be prevented by decreasing the content of unavoidable impurities such as Si, Al and Fe which become starting points for the cracks.

### BRIEF DESCRIPTION OF THE DRAWINGS

FIG. 1 shows a phase diagram of In—Co.

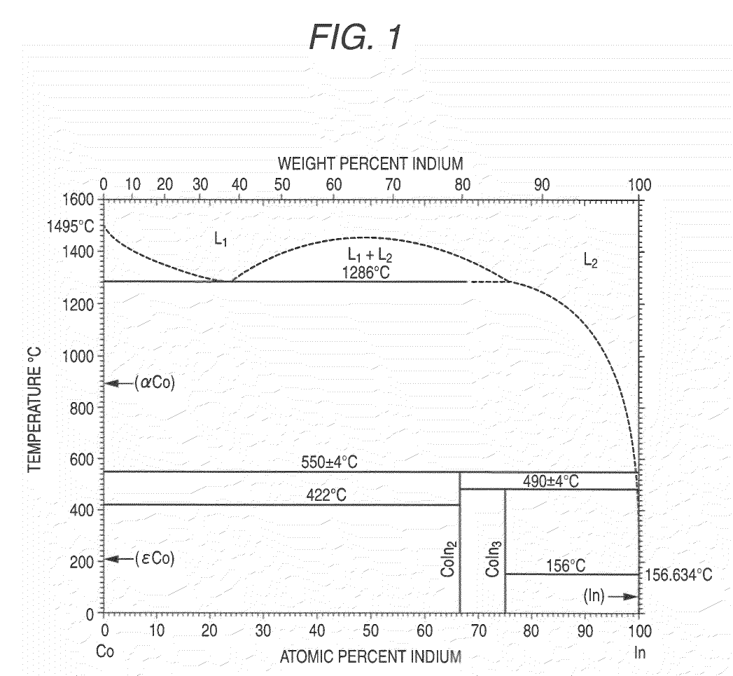

FIG. 2 shows a reflection electron image photograph at a magnification of 1,000 of a sputtering target in Comparative Example 1, taken by using a scanning electron microscope (SEM).

FIG. 3 shows a reflection electron image photograph at a magnification of 1,000 of a sputtering target in Comparative Example 2, taken by using a scanning electron microscope (SEM).

### EXPLANATION OF REFERENCE

1 Black
2 Deep Grey
3 Light Grey
4 White

### DETAILED DESCRIPTION OF THE INVENTION

The invention will be described in greater detail below based on embodiments.

The sputtering target of the invention is not produced only by a production process such as a mere melting process or powder process which is used in the production of general sputtering targets, but is produced by a combined production process of the melting process and the powder process.

For example, when an In alloy sputtering target containing Co in an amount of 40 atomic % is produced, the sputtering target can not be produced at once by the melting process, as previously described. For this reason, an ingot within the composition range where the production thereof by the melting process is possible is once produced by casting according to the melting process. In the case of the ingot containing In and Co, the content of Co is preferably 25±1 atomic % (tolerance) and more preferably 25±0.5 atomic % (tolerance). Then, this ingot is pulverized with a pulverizer or the like to form a main powder. In order to obtain a main powder uniform in particle size, it is necessary to produce an ingot within the composition range where an intermetallic compound (CoIn₃=In-25Co) having strength is obtained.

It is impossible to produce the sputtering target having a predetermined final component composition by only this main powder, so that it is necessary to make up for the content of an insufficient component (element) by some means. Accordingly, a sub-powder of the required component (for example, a Co powder) is prepared. The sub-powder is added to the main powder with an arbitrary ratio, followed by mixing, and then, the resulting mixture is sintered, thereby being able to produce the sputtering target having a predetermined final component composition.

The reason why the sputtering target of the invention contains In as the main component is that since In has a remarkably low melting point (melting point: 156.6° C.) compared to other metals such as Al, Ag and Cu which have hitherto been used in the production of a recording film (including a mask film for thermal lithography, hereinafter also including a mask film for thermal lithography when described as a recording film, unless otherwise specified), the recording film of an In alloy formed is easily melted and deformed to be able to exhibit excellent recording characteristics even at low laser power. Further, when application to BD-R which is a write-once optical disk of the next generation type using a blue laser is considered, it is likely to become difficult to form a recording mark, according to an Al alloy or the like which has been conventionally employed. However, according to the In alloy, there is no such possibility.

Incidentally, in order to allow the recording film formed to sufficiently exhibit recording characteristics thereof, the content of In in the sputtering target is preferably 30 atomic % or more, more preferably 45 atomic % or more, and particularly preferably 50 atomic % or more, and preferably 80 atomic % or less, more preferably 75 atomic % or less, and particularly preferably 70 atomic % or less.

Main elements allowed to be contained together with In in the sputtering target are Co and Ni. The recording film having high reflectance (particularly, initial reflectance) and high C/N ratio of an 8 T signal can be formed by allowing at least one of Co and Ni to be contained. Although a detailed mechanism thereof is not clear, it is deduced that ultra-surface-smoothness, microstructure and surface tension adjustment of the recording film formed are realized at the same time by inclusion of Co or Ni.

When Co is allowed to be contained in the sputtering target, the content thereof is preferably from 20 to 65 atomic %, more preferably from 25 to 60 atomic %, and particularly preferably from 30 to 55 atomic % from the viewpoint of recording characteristics. When the content is less than 20 atomic %, surface smoothness of the recording film formed becomes insufficient, so that media noise relatively increases to result in failure to obtain sufficient high C/N. This is therefore not said to be preferred. On the other hand, when the content exceeds 65 atomic %, the characteristic of the low melting point of In is impaired, resulting in deterioration of recording sensitivity of the recording film formed (an increase in recording laser power for obtaining high C/N). This is therefore not said to be preferred.

Further, the same can be said of the case where Ni is allowed to be contained, and the content thereof is also preferably from 20 to 65 atomic %. In the case of multiple addition, the total content of them is preferably from 20 to 65 atomic % and the content of Ni is preferably from 0 to 25 atomic %, more preferably from 5 to 25 atomic % and particularly preferably from 7 to 20 atomic %.

Incidentally, in addition to Co or Ni, another element can be contained in the sputtering target. However, when the element added is Pt or Au, the reflectance of the recording film formed by addition thereof decreases compared to the recording film formed by addition of Co or Ni, although it exerts an effect on ultra-surface-smoothness of the recording film formed.

Further, contrary to the case of adding Pt or Au, addition of V leads to deterioration of ultra-surface-smoothness of the recording film compared to the recording film formed by addition of Co or Ni, resulting to failure to obtain sufficient high C/N, although high reflectance of the recording film formed can be secured.

Furthermore, at least one element selected from Sn, Ge and Bi can also be added to the sputtering target, as well as addition of Co or Ni to In. In order to decrease a jitter value, the content thereof is preferably 19 atomic % or less, more preferably 1 to 15 atomic %, and particularly preferably 3 to 10 atomic %. Addition of these elements to the sputtering target makes it possible to decrease a jitter value of the recording film formed. Incidentally, the jitter value is an index of uncertainty of a recorded signal mark edge position, and is a value corresponding to a dispersion (σ) at the time when the distribution of rising/falling positions of the edge is determined and taken as a normal distribution. Although a mechanism of being able to decrease the jitter value is not necessarily clear, it is deduced that Sn, Ge and Bi realize the inhibition of lateral heat bleeding by a decrease in thermal conductivity without increasing the melting point.

As described above, the sputtering target of the invention is produced by the complicated production process. First, the ingot within the composition range where the production thereof by the melting process is possible is produced by a vacuum melting process or the like. In the production thereof, contamination with unavoidable impurities such as gas components in the atmosphere or melting furnace components is considered. Further, also at the time of mixing and sintering, contamination with these unavoidable impurities is considered. In the sputtering target of the invention, the total content of Si, Al and Fe as these unavoidable impurities is 300 ppm by mass or less, more preferably 250 ppm by mass or less, and particularly preferably 200 ppm by mass or less. Further, the content of oxygen is preferably 3,000 ppm by mass or less, more preferably 2500 ppm by mass or less, and particularly preferably 2000 ppm by mass or less.

The content of Si and Al as the unavoidable impurities and the content of oxygen can be decreased by using a graphite crucible at the time of melting of a mother alloy, and the like. Therefore, the graphite crucible is preferably used at the time of melting of a mother alloy. The content of Fe as the unavoidable impurities can be decreased by performing magnetic separation after coarse crushing with a jaw crusher or the like, shortening a fine pulverizing time as much as possible, and the like.

### EXAMPLES

Examples of the invention and comparative examples will be described below. Incidentally, the invention should not be construed as being limited to the examples, and may also be carried out with appropriate modifications within the range not departing from the spirit of the invention. All such modifications are included in the scope of the invention.

In the examples, there was produced an ingot consisting of an intermetallic compound within the composition range where the production thereof by the melting process was possible. The component composition of the ingot produced was In-25Co-15Ni (atomic %). A furnace used for the production of this ingot was a vacuum induction furnace (VIF), and casting was performed in a graphite mold using a graphite crucible under conditions of an Ar pressure of an inert atmosphere of 9.3×10⁴ Pa and a temperature of 1,290° C. Then, the resulting ingot was pulverized to form a main powder. The pulverization was performed by coarsely crushing the ingot with a jaw crusher, followed by fine pulverization with an M-4 type free pulverizer manufactured by Nara Machinery Co., Ltd.

As described above, the component composition of the main powder is In-25Co-15Ni (atomic %), whereas the predetermined final component composition of the sputtering target to be produced is In-40.3Co-11.9Ni-5.0Sn (atomic %) Accordingly, in order to make up for the content of components (elements) insufficient to the predetermined final component composition when only the main powder was used, a Co powder (Co Powder 400 Mesh manufactured by UMICORE) and a Sn powder (AT-Sn No. 200 manufactured by Yamaishi Metal Co., Ltd.) were prepared as sub-powders. The Co powder and the Sn powder as the sub-powders were mixed with this main powder, followed by rotation in a V-mixer at 20 revolutions/min for 45 minutes to obtain a mixed powder. Incidentally, the reason why the atomic % of Ni is 11.9 atomic % in the predetermined final component composition of the sputtering target to be produced, compared with that the atomic % of Ni is 15 atomic % in the component composition of the main powder, is that the atomic % of Ni relatively decreases with increases in atomic % of Co and Sn in the total atomic weight by mixing of the sub-powders.

This mixed powder was sintered, thereby producing the desired sputtering target. A sintering machine used for sintering was a spark plasma sintering machine, SPS-3, 20Mk-4, manufactured by Sumitomo Heavy Industries, Ltd., and using a graphite mold having a diameter of 210 mm, and the sputtering target was produced at heating temperature of 390° C. and an applied pressure of 50 kN.

In Examples 1 to 4 shown in Table 1, use of the graphite crucible at the time of melting of the mother alloy decreased the content of Si and Al as the unavoidable impurities and the content of oxygen. Further, magnetic separation was performed after coarse crushing with the jaw crusher, and the fine pulverizing time was shortened as much as possible, thereby decreasing the content of Fe as the unavoidable impurity. Incidentally, the reason why there were differences in the content of the unavoidable impurities among Examples 1 to 4 was that production conditions thereof were adjusted. In particular, the reason why there were differences in the content of Al was that even in the case of using the graphite crucible, variations in the state of cleaning occurred when an alumina crucible used in the preceding batch was exchanged by the graphite crucible, so that adjustment was made supposing the conditions thereof. Further, differences in the content of oxygen were caused by fluctuations due to variations in degree of oxidation at the time of pulverization, because pulverization was performed in the air. As compared therewith, in Comparative Examples 1 and 2, an alumina crucible was used as the crucible at the time of melting of the mother alloy, magnetic separation was not performed after coarse crushing with the jaw crusher, and the fine pulverizing time was longer than that of Examples 1 to 4. Thus, measures to decrease the content of Si, Al and Fe which are the unavoidable impurities and the content of oxygen were not taken.

Further, in the case of Examples 1 to 4 and Comparative Example 1, 910 g of the Co powder and 470 g of the Sn powder were mixed with 5,400 g of the main powder having the component composition of In-25Co-15Ni (atomic %) to form a mixed powder. In the case of Comparative Example 2, 800 g of the Co powder and 240 g of the Sn powder were mixed with 5,400 g of that main powder to form a mixed powder. Using this mixed powder, each sputtering target was produced. Incidentally, the above-mentioned values somewhat vary, because a final target shape also varies according to a sputtering apparatus.

In Table 1, there are shown the content of each of Si, Al and Fe in the unavoidable impurities of the sputtering target, the total content thereof and the O (oxygen) content, respectively. The unit of the respective numerical values shown in Table 1 is ppm by mass. Si was analyzed by a light absorption method, Al was analyzed by flameless atomic absorption spectrometry, Fe was analyzed by ICP analysis, and O was analyzed by an inert gas melting method. The numerical values indicated by an inequality sign (<) in Table 1 show that they were less than a lower detection limit analyzable by each analysis method shown above.

TABLE 1

| | | | | | Comparative | Comparative |
|---|---|---|---|---|---|---|
| | Example 1 | Example 2 | Example 3 | Example 4 | Example 1 | Example 2 |
| Si | 100 | 100 | 100 | 100 | 220 | 200 |
| Al | 30 | 10 | 10 | <10 | 50 | 60 |
| Fe | <10 | <10 | <10 | <10 | 50 | 80 |
| Si + Al + Fe | 130 | 110 | 110 | 100 | 320 | 340 |
| O | 1500 | 1600 | 2400 | 1500 | 3200 | 3400 |

The sputtering targets obtained in Examples 1 to 4 and Comparative Examples 1 and 2 were each examined. As a result, no target cracks occurred in Examples 1 to 4 in which the total content of Si, Al and Fe was 300 ppm by mass or less, but target cracks occurred in Comparative Examples 1 and 2 in which the total content of Si, Al and Fe exceeded 300 ppm by mass. Similarly, no target cracks occurred in Examples 1 to 4 in which the oxygen content was 3,000 ppm by mass or less, but target cracks occurred in Comparative Examples 1 and 2 in which the oxygen content exceeded 3,000 ppm by mass.

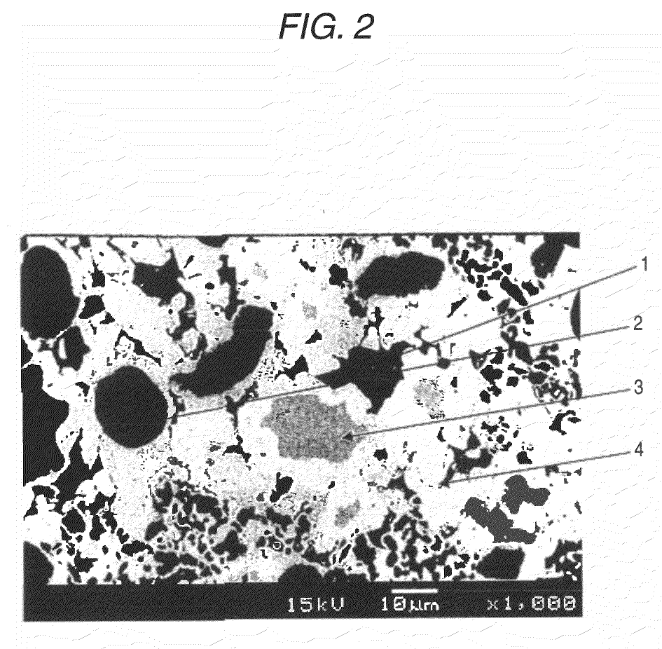

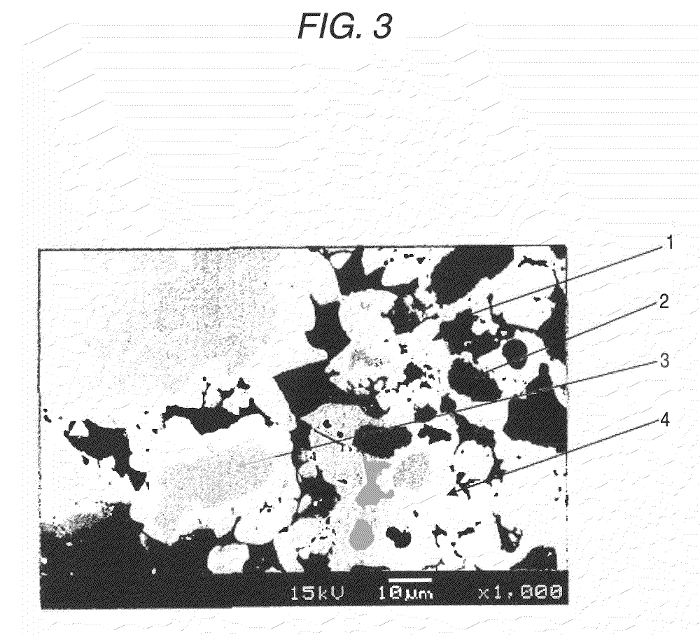

In order to examine the cause of the occurrence of the target cracks, tissue observation was performed under a scanning electron microscope (SEM) for the respective sputtering targets of Comparative Examples 1 and 2 in which the cracks occurred. Reflection electron image photographs at a magnification of 1,000 of the sputtering targets in Comparative Examples 1 and 2 are shown in FIGS. 2 and 3, respectively. EDX analysis was made for respective places indicated by numbers 1 to 4 in the photographs to examine the content of Si, Al, Fe and O. The results thereof are shown in Table 2. Si, Al, Fe and O were detected in large amounts in black-ground places indicated by number 1 in the photographs. Incidentally, the unit of the respective numerical values shown in Table 2 is also ppm by mass.

TABLE 2

| | Number 1 of | Numbers 2 to 4 | Number 1 of | Numbers 2 to 4 |
|---|---|---|---|---|
| | Comparative | of Comparative | Comparative | of Comparative |
| | Example 1 | Example 1 | Example 2 | Example 2 |
| Si | 17,300 | 13,000 to | 15,200 | 13,000 to 15,000 |
| | | 19,000 | | |
| Al | 2,400 | Lower detection | 2,000 | Lower detection |
| | | limit or less | | limit or less |
| Fe | 82,600 | Lower detection | 84,800 | Lower detection |
| | | limit or less | | limit or less |
| O | 230,000 | Lower detection | 231,000 | 231,200 |
| | | limit or less | | |

The Vickers hardness was examined. As a result, it was from 300 to 400 in places indicated by numbers 2 to 4 in the photographs of both Comparative Examples 1 and 2. As compared therewith, it was from 50 to 100 in the places indicated by number 1 in the photographs, in which Si, Al, Fe and O were detected in large amounts, thus forming low density phases. Microstructures of sites where target cracks occurred were observed under an optical microscope. As a result, it was confirmed that the phases containing much impurities, in which Si, Al, Fe and O were detected in large amounts, become starting points for the target cracks.

1. A sputtering target produced by mixing and sintering a main powder containing In as a main component, which is obtained by pulverizing an ingot consisting of an intermetallic compound, and a sub-powder containing a component composition different from the main powder, wherein the total content of Si, Al and Fe which are unavoidable impurities is 300 ppm by mass or less.

2. The sputtering target according to claim 1, which contains In and an intermetallic compound containing at least one element selected from the group consisting of Co and Ni.

3. The sputtering target according to claim 1, which contains Co in an amount of 20 to 65 atomic %.

4. The sputtering target according to claim 2, which contains Co in an amount of 20 to 65 atomic %.

5. The sputtering target according to claim 2, which further contains at least one element selected from the group consisting of Sn, Ge and Bi.

6. The sputtering target according to claim 3, which further contains at least one element selected from the group consisting of Sn, Ge and Bi.

7. The sputtering target according to claim 4, which further contains at least one element selected from the group consisting of Sn, Ge and Bi.

8. The sputtering target according to claim 1, wherein a content of oxygen is 3,000 ppm by mass or less.

9. The sputtering target according to claim 2, wherein a content of oxygen is 3,000 ppm by mass or less.

10. The sputtering target according to claim 3, wherein a content of oxygen is 3,000 ppm by mass or less.

11. The sputtering target according to claim 4, wherein a content of oxygen is 3,000 ppm by mass or less.

12. The sputtering target according to claim 5, wherein a content of oxygen is 3,000 ppm by mass or less.

13. The sputtering target according to claim 6, wherein a content of oxygen is 3,000 ppm by mass or less.

14. The sputtering target according to claim 7, wherein a content of oxygen is 3,000 ppm by mass or less.
